(19) United States
(12) Patent Application Publication
(10) Pub. No.: US 2005/0106873 A1
(43) Pub. Date: May 19, 2005

(54) Plasma chamber having multiple RF source frequencies

(76) Inventors: Daniel J. Hoffman, Saratoga, CA (US); Diana Xiaobing Ma, Saratoga, CA (US); Yan Ye, Saratoga, CA (US); Jang Gyoo Yang, Sunnyvale, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(21) Appl. No.: 10/890,034

(22) Filed: Jul. 12, 2004

Related U.S. Application Data
(60) Provisional application No. 60/495,523, filed on Aug. 15, 2003.

(51) Int. Cl. H01L 21/302; H01L 21/461

(52) U.S. Cl. 438/689

(57) ABSTRACT

A method and apparatus for processing a semiconductor substrate is disclosed. A plasma reactor has a capacitive electrode driven by a plurality of RF power sources, and the electrode capacitance is matched at the desired plasma density and RF source frequency to the negative capacitance of the plasma, to provide an electrode plasma resonance supportive of a broad process window within which the plasma may be sustained.

### CROSS-REFERENCE TO RELATED APPLICATIONS

This application claims benefit of United States provisional patent application Ser. No. 60/495,523, filed Aug. 15, 2003, which is herein incorporated by reference.

### BACKGROUND OF THE INVENTION

1. Field of the Invention

This invention relates generally to plasma enhanced semiconductor substrate processing equipment and, more specifically, to a method and apparatus for processing semiconductor substrates utilizing multiple radio frequency (RF) sources and a common matching circuit.

2. Description of Related Art

An RF plasma reactor is used to process semiconductor substrates to produce microelectronic circuits. The reactor forms a plasma within a chamber containing the substrate to be processed. The plasma is formed and maintained by application of RF plasma source power coupled either inductively or capacitively into the chamber. For capacitive coupling of RF source power into the chamber, an overhead electrode (facing the substrate) is powered by an RF source power generator.

To optimize the power that is capacitively coupled to the plasma, the output impedance of the RF generator, typically 50 Ohms, must be matched to the load impedance presented by the combination of the electrode and the plasma. Otherwise, the amount of RF power delivered to the plasma chamber will fluctuate with fluctuations in the plasma load impedance so that certain process parameters such as plasma density cannot be maintained within the required limits. The plasma load impedance fluctuates during processing because it depends upon conditions inside the reactor chamber which tend to change dynamically as processing progresses. At an optimum plasma density for dielectric or metal etch processes, the load impedance is very small compared to the output impedance of the RF generator and can vary significantly during the processing of the substrate. Accordingly, an impedance match circuit must be employed to actively maintain an impedance match between the generator and the load. Such active impedance matching uses either a variable reactance, i.e., (physically tuning the values of circuit element) and/or a variable frequency (i.e., tuning the input frequency to center the frequency within the match bandwidth). One problem with such impedance match circuits is that they must be sufficiently agile to follow rapid changes in the plasma load impedance, and therefore are relatively expensive and can reduce system reliability due to their complexity.

Another problem is that the range of load impedances over which the match circuit can provide an impedance match (the “match space”) is limited. The match space is related to the system Q, where Q=Δf/f, f being a resonant frequency of the system and Δf being the bandwidth on either side of f within which the resonant amplitude is within 6 dB of the peak resonant amplitude at f. The typical RF generator has a limited ability to maintain the forward power at a nearly constant level even as more RF power is reflected back to the generator as the plasma impedance fluctuates. Typically, this is achieved by the generator adjusting its forward power level, so that as an impedance mismatch increases (and therefore reflected power increases), the generator increases its forward power level. Of course, this ability is limited by the maximum forward power that the generator is capable of producing. Typically, the generator is capable of handling a maximum ratio of forward standing wave voltage to reflected wave voltage (i.e., the voltage standing wave ratio or VSWR) of not more than 3:1. If the difference in impedances increases (e.g., due to plasma impedance fluctuations during processing) so that the VSWR exceeds 3:1, then the RF generator can no longer control the delivered power, and control over the plasma is lost. As a result, the process is likely to fail. Therefore, at least an approximate impedance match must be maintained between the RF generator and the load presented to it by the combination of the electrode and the chamber. This approximate impedance match must be sufficient to keep the VSWR at the generator output within the 3:1 VSWR limit over the entire anticipated range of plasma impedance fluctuations. The impedance match space is, typically, the range of load impedances for which the match circuit can maintain the VSWR at the generator output at or below 3:1.

A related problem is that the load impedance itself is highly sensitive to process parameters such as chamber pressure, source power level, source power frequency and plasma density. This limits the range of such process parameters (the “process window”) within which the plasma reactor must be operated to avoid an unacceptable impedance mismatch or avoid fluctuations that take load impedance outside of the match space. Likewise, it is difficult to provide a reactor which can be operated outside of a relatively narrow process window and use, or one that can handle many applications.

Another related problem is that the load impedance is also affected by the configuration of the reactor itself, such as dimensions of certain mechanical features and the conductivity or dielectric constant of certain materials within the reactor. (Such configurational items affect reactor electrical characteristics, such as stray capacitance for example, that in turn affect the load impedance.) This makes it difficult to maintain uniformity among different reactors of the same design due to manufacturing tolerances and variations in materials. As a result, with a high system Q and correspondingly small impedance match space, it is difficult to produce any two reactors of the same design which exhibit the same process window or provide the same performance.

Another problem is inefficient use of the RF power source. Plasma reactors are known to be inefficient, in that the amount of power delivered to the plasma tends to be significantly less than the power produced by the RF generator. As a result, an additional cost in generator capability and a trade-off against reliability must be incurred to produce power in excess of what is actually required to be delivered into the plasma.

Therefore, there is a need in the art for a technique to efficiently couple RF power to a plasma within a plasma reactor as well as provide a wide process window.

### SUMMARY OF THE INVENTION

The invention is a plasma reactor having a capacitive electrode driven by a plurality of RF power sources, and the electrode capacitance is matched at the desired plasma density and RF source frequency to the negative capacitance of the plasma, to provide an electrode plasma resonance and a broad process window within which the plasma may be sustained. Each RF power source is coupled to a coaxial stub that forms a common, fixed matching circuit for both sources.

In a specific embodiment of the invention a plurality of RF sources are each impedance-matched to the electrode-plasma load impedance through a tuning stub connected at one end to the electrode. The stub has a length providing a resonance at or near the frequency of the RF sources and/or the resonant frequency of the electrode-plasma combination. Each RF generator is coupled to the stub at or near a location along the stub at which the input impedance matches the RF source impedance, i.e., a first source is coupled to the input coax at a point that is about λ/4 wavelength from a short at a first frequency and a second source having a second frequency is coupled about λ/4 wavelength from a short at a second frequency.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional side view of a plasma reactor embodying the present invention; and

FIGS. 2A and 2B are diagrams illustrating, respectively, the coaxial stub of FIG. 1 and the voltage and current standing wave amplitudes as a function of position along the coaxial stub.

### DETAILED DESCRIPTION

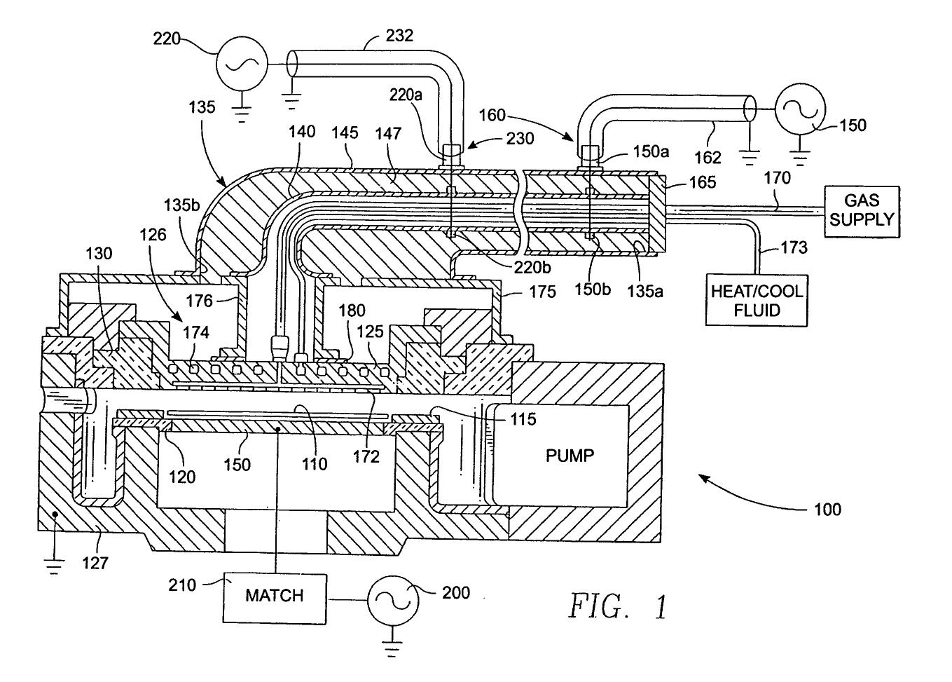

Referring to FIG. 1, a plasma reactor includes a reactor chamber 100 with a substrate support 105 at the bottom of the chamber supporting a semiconductor substrate 110. A semiconductor ring 115 surrounds the substrate 110. The semiconductor ring 115 is supported on the grounded chamber body 127 by a dielectric (quartz) ring 120. In one embodiment, the ring 120 has a thickness of 10 mm and dielectric constant of 4. The chamber 100 is bounded at the top by a disc shaped overhead aluminum electrode supported at a predetermined gap length above the substrate 110 on the grounded chamber body 127 by a dielectric (quartz) seal. The overhead electrode 125 also may be a metal (e.g., aluminum) that may be covered with a semi-metal material (e.g., Si or SiC) on its interior surface, or it may be itself a semi-metal material. A first RF generator 150 having a first frequency and a second RF generator 220 having a second frequency apply RF power to the electrode 125. RF power from both generators 150, 220 is coupled through a coaxial cable 162 matched to the generator 150 and into a coaxial stub 135 connected to the electrode 125. The stub 135 has a characteristic impedance, resonance frequency, and provides an impedance match between the electrode 125 and the RF power generators 150, 220, as will be more fully described below. The chamber body is connected to the RF return (RF ground) of the RF generators 150, 220. The RF path from the overhead electrode 125 to RF ground is affected by the capacitance of the semiconductor ring 115, the dielectric ring 120 and the dielectric seal 130. The substrate support 105, the substrate 110 and the semiconductor ring 115 provide the primary RF return path for RF power applied to the electrode 125.

In one embodiment of the invention, the capacitance of the overhead electrode assembly 126, including the electrode 125, the dielectric ring 120 and dielectric seal 130 measured with respect to RF return or ground is about 180 pico farads. The electrode assembly capacitance is affected by the electrode area, the gap length (distance between substrate support and overhead electrode), and by factors affecting stray capacitances, especially the dielectric values of the seal 130 and of the dielectric ring 120, which in turn are affected by the dielectric constants and thicknesses of the materials employed. More generally, the capacitance of the electrode assembly (an unsigned number or scalar) is equal or nearly equal in magnitude to the negative capacitance of the plasma (a complex number) at a particular source power frequency, plasma density and operating pressure, as will be discussed below.

Many of the factors influencing the foregoing relationship are in great part predetermined due to the realities of the plasma process requirements needed to be performed by the reactor, the size of the substrate, and the requirement that the processing be carried out uniformly over the substrate. Thus, the plasma capacitance is a function of the plasma density and the source power frequency, while the electrode capacitance is a function of the substrate support-to-electrode gap (height), electrode diameter, and dielectric values of the insulators of the assembly. Plasma density, operating pressure, gap, and electrode diameter must satisfy the requirements of the plasma process to be performed by the reactor. In particular, the ion density must be within a certain range. For example, silicon and dielectric plasma etch processes generally require the plasma ion density to be within the range of 10⁹-10¹² ions/cc. The substrate electrode gap provides an optimum plasma ion distribution uniformity for 8 inch substrates, for example, if the gap is about 2 inches. The electrode diameter is generally at least as great as, if not greater than the diameter of the substrate. Operating pressures similarly have practical ranges for typical etch and other plasma processes.

It has been found that other factors remain that can be selected to achieve the above relationship, particularly choice of source frequency and choice of capacitances for the overhead electrode assembly 126. Within the foregoing dimensional constraints imposed on the electrode and the constraints (e.g., density range) imposed on the plasma, the electrode capacitance can be matched to the magnitude of the negative capacitance of the plasma if the source power frequency is selected to be a VHF frequency, and if the dielectric values of the insulator components of electrode assembly 126 are selected properly. Such selection can achieve a match or near match between source power frequency and plasma-electrode resonance frequency.

Accordingly in one embodiment, for an 8-inch substrate, the overhead electrode diameter is approximately 11 inches, the gap is about 2 inches, the plasma density and operating pressure is typical for etch processes as above-stated, the dielectric material for the seal 130 has a dielectric constant of about 9 and a thickness of the order of 1 inch, the ring 115 has an inner diameter of slightly in excess of 10 inches and an outer diameter of about 13 inches, the ring 120 has a dielectric constant of about 4 and a thickness of the order of 10 mm, the VHF source power frequencies are 162 MHz and 215 MHz (although other VHF frequencies could be equally effective), and for both of the source power frequencies, the plasma electrode resonance frequency and the stub resonance frequency are all matched or nearly matched.

More particularly, in one embodiment, these frequencies are slightly offset from one another, with the source power frequencies being 162 MHz and 215 MHz, the corresponding electrode-plasma resonant frequency and the stub frequency are selected to be between the source frequencies, e.g., about 188 MHz, in order to achieve a de-tuning effect which advantageously reduces the system Q. Such a reduction in system Q renders the reactor performance less susceptible to changes in conditions inside the chamber, so that the entire process is much more stable and can be performed over a far wider process window.

The coaxial stub 135 is a specially configured design that further contributes to the overall system stability, its wide process window capabilities, as well as many other valuable advantages. It includes an inner cylindrical conductor 140 and an outer concentric cylindrical conductor 145. An insulator 147 (denoted by cross-hatching in FIG. 1) having a relative dielectric constant of about 1 fills the space between the inner and outer conductors 140, 145. The inner and outer conductors 140, 145 are formed of nickel-coated aluminum. In one embodiment, the outer conductor 145 has a diameter of about 4.32 inches and the inner conductor 140 has a diameter of about 1.5 inches. The stub characteristic impedance is determined by the radii of the inner and outer conductors 140, 145 and the dielectric constant of the insulator 147. The stub 135 of the embodiment described above has a characteristic impedance of 65 Ω. More generally, the stub characteristic impedance exceeds power output impedance of the sources 150, 220 by about 20%-40% and in one embodiment by about 30%. The stub 135 has an axial length of about 39 inches—a half wavelength at 188 MHz, respectively—in order to have a resonance in the vicinity of 188 MHz, a frequency between the VHF source power frequencies of 162 MHz and 215 MHz.

Taps 160, 230 are provided at particular points along the axial length of the stub 135 for applying RF power from the RF generators 150, 220 to the stub 135, as will be discussed below. The RF power terminals 150a, 220a and the RF return terminals 150b, 220b of the generators 150, 220 are connected at the taps 160, 230 on the stub 135 to the inner and outer coaxial stub conductors 140, 145, respectively. These connections are made via a generator-to-stub coaxial cable 162, 232 having a characteristic impedance that matches the output impedance of the generator 150, 220 (typically, 50 Ω) in the well-known manner. A terminating conductor 165 at the far end 135a of the stub 135 shorts the inner and outer conductors 140, 145 together, so that the stub 135 is shorted at its far end 135a. At the near end 135b (the unshorted end) of the stub 135, the outer conductor 145 is connected to the chamber body via an annular conductive housing or support 175, while the inner conductor 140 is connected to the center of electrode 125 via a conductive cylinder or support 176. A dielectric ring 180, which in one embodiment has a thickness of about 1.3 inches and dielectric constant of about 9, is held between and separates the conductive cylinder 176 and the electrode 125.

The inner conductor 140 generally provides a conduit for utilities such as process gases and coolant. The principal advantage of this feature is that, unlike typical plasma reactors, the gas line 170 and the coolant line 173 do not cross large electrical potential differences. They therefore may be constructed of metal, a less expensive and more reliable material for such a purpose. The metallic gas line 170 feeds gas inlets 172 in or adjacent the overhead electrode 125 while the metallic coolant line 173 feeds coolant passages or jackets 174 within the overhead electrode 125.

An active and resonant impedance transformation is thereby provided by this specially configured stub match between the RF generators 150, 220, and the overhead electrode assembly 126 and processing plasma load, minimizing reflected power and providing a very wide impedance match space accommodating wide changes in load impedance. Consequently, wide process windows and process flexibility is provided, along with previously unobtainable efficiency in use of power, all while minimizing or avoiding the need for typical impedance match apparatus. As noted above, the stub resonance frequency is also offset from ideal match to further enhance overall system Q, system stability and process windows and multi-process capability.

As outlined above, a principal feature is to configure the overhead electrode assembly 126 for resonance with the plasma at the electrode-plasma resonant frequency and for the matching (or the near match on the source power frequency and the electrode-plasma frequency. The electrode assembly 126 has a predominantly capacitive reactance while the plasma reactance is a complex function of frequency, plasma density and other parameters. (As will be described below in greater detail, a plasma is analyzed in terms of a reactance which is a complex function involving imaginary terms and generally corresponds to a negative capacitance.) The electrode-plasma resonant frequency is determined by the reactances of the electrode assembly 126 and of the plasma (in analogy with the resonant frequency of a capacitor/inductor resonant circuit being determined by the reactances of the capacitor and the inductor). Thus the electrode-plasma resonant frequencies may not necessarily be either of the source power frequencies, depending as it does upon the plasma density. The problem, therefore, in performing the invention, is to find source power frequencies at which the plasma reactance is such that the electrode-plasma resonant frequency is equal or nearly equal to both of the source power frequencies, given the constraints of practical confinement to a particular range of plasma density and electrode dimensions. The problem is even more difficult, because the plasma density (which affects the plasma reactance) and the electrode dimensions (which affect electrode capacitance) must meet certain process constraints. Specifically, for dielectric and metal plasma etch processes, the plasma density should be within the range of 10⁹-10¹² ions/cc, which is a constraint on the plasma reactance. Moreover, a more uniform plasma ion density distribution for processing 8-inch diameter substrates for example, is realized by a substrate-to-electrode gap or height of about 2 inches and an electrode diameter on the order of the substrate diameter, or greater, which is a constraint on the electrode capacitance.

By matching (or nearly matching) the electrode capacitance to the magnitude of the negative capacitance of the plasma, the electrode-plasma resonant frequency and both of the source power frequencies are at least nearly matched. For the general metal and dielectric etch process conditions enumerated above (i.e., plasma density between 10⁹-10¹² ions/cc, a 2-inch gap and an electrode diameter on the order of roughly 11 inches), the match is possible if the source power frequencies are in the VHF frequency band. Other conditions (e.g., different substrate diameters, different plasma densities, etc.) may dictate a different frequency range to realize such a match in performing this feature of the invention. As will be detailed below, under favored plasma processing conditions for processing 8-inch substrates in several principal applications including dielectric and metal plasma etching and chemical vapor deposition, the plasma capacitance in one typical working example having plasma densities as set forth above was between −50 and −400 pico farads. In this embodiment the capacitance of the overhead electrode assembly 126 was matched to the magnitude of this negative plasma capacitance by using an electrode diameter of 11 inches, a gap length (electrode to pedestal spacing) of approximately 2 inches, choosing a dielectric material for seal 130 having a dielectric constant of 9, and a thickness of the order of one inch, and a dielectric material for the ring 120 having a dielectric constant of 4 and thickness of the order of 10 mm.

The combination of electrode assembly 126 and the plasma resonates at an electrode-plasma resonant frequency that falls between the power frequencies applied to the electrode 125, assuming a matching of their capacitances as just described. For favored etch plasma processing recipes, environments and plasmas, this electrode-plasma resonant frequency and the source power frequencies can be matched or nearly matched at VHF frequencies; and that it is highly advantageous that such a frequency match or near-match be implemented. The source power frequencies are 162 MHz and 215 MHz, with the resonant frequency falling in between the two source frequencies. In one embodiment, the electrode-plasma resonance frequency corresponding to the foregoing values of plasma negative capacitance is approximately 188 MHz.

The plasma capacitance is a function of among other things, plasma electron density. This is related to plasma ion density, which needs, in order to provide good plasma processing conditions, to be kept in a range generally 10⁹ to 10¹² ions/cc. This density, together with the source power frequencies and other parameters, determines the plasma negative capacitance, the selection of which is therefore constrained by the need to optimize plasma processing conditions, as will be further detailed below. But the overhead electrode assembly capacitance is affected by many physical factors, e.g. gap length (spacing between electrode 125 and the substrate); the area of electrode 125; the choice of dielectric constant of the dielectric seal 130 between electrode 125 and grounded chamber body 127; the choice of dielectric constant for the dielectric ring 120 between semiconductor ring 115 and the chamber body; and the thickness of the dielectric structures of seal 130 and ring 120 and the thickness and dielectric constant of the ring 180. This permits some adjustment of the electrode assembly capacitance through choices made among these and other physical factors affecting the overhead electrode capacitance. The range of this adjustment is sufficient to achieve the necessary degree of matching of the overhead electrode assembly capacitance to the magnitude of the negative plasma capacitance. In particular, the dielectric materials and dimensions for the seal 130 and ring 120 are chosen to provide the desired dielectric constants and resulting dielectric values. Matching the electrode capacitance and the plasma capacitance can then be achieved despite the fact that some of the same physical factors influencing electrode capacitance, particularly gap length, will be dictated or limited by the following practicalities: the need to handle larger diameter substrates; to do so with good uniformity of distribution of plasma ion density over the full diameter of the substrate; and to have good control of ion density vs. ion energy.

For plasma ion density ranges as set forth above favorable to plasma etch processes; and for chamber dimensions suitable for processing 8 inch substrates, a capacitance for electrode assembly 126 was achieved which matched the plasma capacitance of −50 to −400 pico farads by using an electrode diameter of 11 inches, a gap length of approximately 2 inches, and a material for the seal 130 having a dielectric constant of about 9, and a material for the ring 120 having a dielectric constant of about 4.

Given the foregoing range for the plasma capacitance and the matching overhead electrode capacitance, the electrode-plasma resonance frequency was approximately between the source power frequencies of 162 MHz and 215 MHz.

A great advantage of choosing the capacitance of the electrode assembly 126 in this manner, and then matching the resultant electrode-plasma resonant frequency and the source power frequencies, is that resonance of the electrode and plasma between the two source power frequencies provides a wider impedance match and wider process window, and consequently much greater immunity to changes in process conditions, and therefore greater performance stability. The entire processing system is rendered less sensitive to variations in operating conditions, e.g., shifts in plasma impedance, and therefore more reliable along with a greater range of process applicability. As will be discussed later in the specification, this advantage is further enhanced by the small offset between the electrode-plasma resonant frequency and the source power frequency.

The stub 135 provides an impedance transformation between the 50 Ω output impedance of the RF generators 150, 230 and the load impedance presented by the combination of the electrode assembly 126 and the plasma within the chamber. For such an impedance match, there must be little or no reflection of RF power at the generator-stub connection and at the stub-electrode connection (at least no reflection exceeding the VSWR limits of the RF generator 150, 230). How this is accomplished will now be described.

At a frequency near the desired VHF frequencies of the generators 150, 230 (i.e., 188 MHz) and at a plasma density and chamber pressure favorable for plasma etch processes (i.e., 10⁹-10¹² ions/cm³ and 10 mT-200 mT, respectively), the impedance of the plasma itself is about (0.3+(i)7) Ω, where 0.3 is the real part of the plasma impedance, i=(−1)^{1/2}, and 7 is the imaginary part of the plasma impedance. The load impedance presented by the electrode-plasma combination is a function of this plasma impedance and of the capacitance of the electrode assembly 126. As described above in the working example, the capacitance of the electrode assembly 126 is selected to achieve a resonance between the electrode assembly 126 and the plasma with an electrode-plasma resonant frequency of about 188 MHz. Reflections of RF power at the stub-electrode interface are minimized or avoided because the resonant frequency of the stub 135 is set to be at or near the electrode-plasma resonant frequency so that the two at least nearly resonate together.

At the same time, reflections of RF power at the generator-stub interface are minimized or avoided because the location of the taps 160, 230 along the axial length of the stub 135 are such that, at the taps 160, 230, the ratio of the standing wave voltage to the standing wave current in the stub 135 is near the output impedance of the generators 150, 220 or characteristic impedance of the cable 162 (both being about 50 Ω). How the taps 160, 230 are located to achieve this will now be discussed.

The axial length of the coaxial stub 135 is a multiple of a quarter wavelength of a “stub” frequency (e.g., 188 MHz) which, as stated above, is near the electrode-plasma resonant frequency. In one embodiment of the invention, this multiple is two, so that the coaxial stub length is about a half wavelength of the “stub” frequency, or about 31 inches.

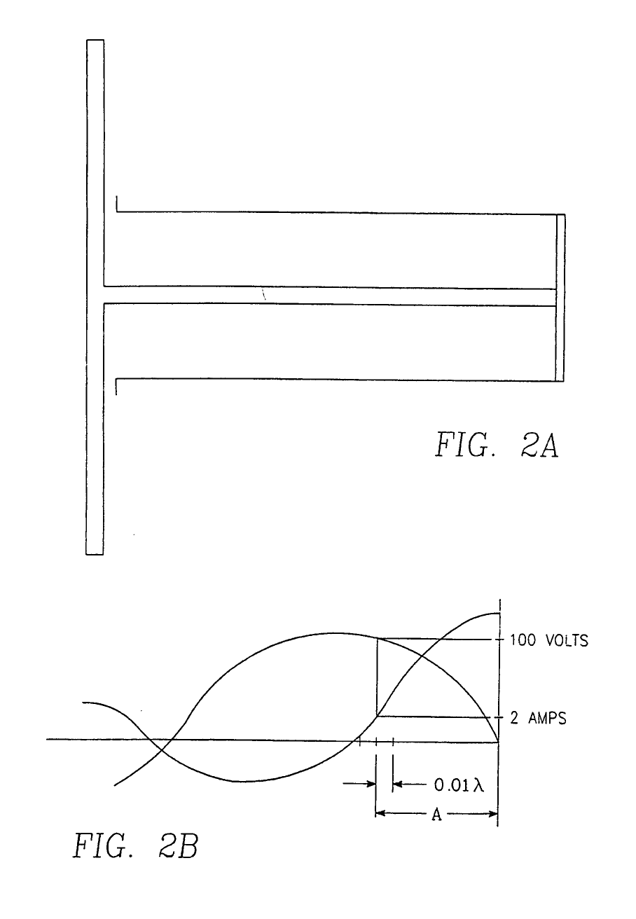

For a match of a system employing one frequency source, the tap 160 is at a particular axial location along the length of the stub 135. At this location, the ratio between the amplitudes of the standing wave voltage and the standing wave current of an RF signal at the output frequency of the generator 150 corresponds to an input impedance matching the output impedance of the RF generator 150 (e.g., 50 Ohms). This is illustrated in FIGS. 2A and 2B, in which the voltage and current standing waves in the stub 135 have a null and a peak, respectively, at the shorted outer stub end 135a. A desired location for the tap 160 is at a distance A inwardly from the shorted end, where the ratio of the standing wave voltage and current corresponds to 50 Ohms. This location is readily found by the skilled worker by empirically determining where the standing wave ratio is 50 Ohms. The distance or location A of the tap 160 that provides a match to the RF generator output impedance (50 Ω) is a function of the characteristic impedance of the stub 135, as will be described later in this specification. When the tap 160 is located precisely at the distance A, the impedance match space accommodates a 9:1 change in the real part of the load impedance, if the RF generator is of the typical kind that can maintain constant delivered power over a 3:1 voltage standing wave ratio (VSWR).

In an embodiment with two RF power sources, the impedance match space is greatly expanded to accommodate a nearly 60:1 change in the real part of the load impedance. This dramatic result is achieved by slightly shifting the taps 160, 230 from the approximate 50 Ω point. The tap 160 for the higher source frequency would be located closer to the shorted external end 135a of the coaxial stub 135 while the tap for the lower source frequency would be located further from the shorted external end 135a of the coaxial stub 135 and past the approximate 50 Ω point. It is a discovery of the invention that at these shifted tap locations, the RF current contribution at the taps 160, 230 subtracts or adds to the current in the stub, whichever becomes appropriate, to compensate for fluctuations in the plasma load impedance. This compensation is sufficient to increase the match space from one that accommodates a 9:1 swing in the real part of the load impedance to a 60:1 swing.

It is felt that this behavior is due to a tendency of the phase of the standing wave current in the stub 135 to become more sensitive to an impedance mismatch with the electrode-plasma load impedance, as the tap point is moved away from the “match” location at A. As described above, the electrode assembly 126 is matched to the negative capacitance of the plasma under nominal operating conditions. This capacitance is −50 to −400 pico farads at a frequency near the VHF source power frequencies (162 MHz and 215 MHz). At this capacitance, the plasma exhibits a plasma impedance of about (0.3+i7) Ω. Thus, 0.3 Ω is the real part of the plasma impedance for which the system is tuned. As plasma conditions fluctuate, the plasma capacitance and impedance fluctuate away from their nominal values. As the plasma capacitance fluctuates from that to which the electrode 125 was matched, the phase of the electrode-plasma resonance changes, which affects the phase of the current in the stub 135. As the phase of the stub's standing wave current thus shifts, the RF generator currents supplied to the taps 160, 230 will either add to or subtract from the stub standing wave current, depending upon the direction of the phase shift. The taps 160, 230 will be displaced from an approximate 50 Ω location.

This expansion of the match space to accommodate a 60:1 swing in the real part of the load impedance enhances process window and reliability of the reactor. This is because as operating conditions shift during a particular process or application, or as the reactor is operated with different operating recipes for different applications, the plasma impedance will change, particularly the real part of the impedance. In the prior art, such a change could readily exceed the range of the conventional match circuit employed in the system, so that the delivered power could no longer be controlled sufficiently to support a viable process, and the process could fail. In the present invention, the range of the real part of the load impedance over which delivered power can be maintained at a desired level has been increased so much that changes in plasma impedance, which formerly would have led to a process failure, have little or no effect on a reactor embodying this aspect of the invention. Thus, the invention enables the reactor to withstand far greater changes in operating conditions during a particular process or application. Alternatively, it enables the reactor to be used in many different applications involving a wider range of process conditions, a significant advantage.

As a further advantage, the coaxial stub 135 that provides this broadened impedance match is a simple passive device with no “moving parts” such as a variable capacitor/servo or a variable frequency/servo typical of conventional impedance match apparatus. It is thus inexpensive and far more reliable than the impedance match apparatus that it replaces.

By using two source frequencies that produce a resonant frequency at an approximate 50 Ω point, the system has been somewhat “de-tuned”. It therefore has a lower “Q”. The use of the two source power frequencies proportionately decreases the Q as well (in addition to facilitating the match of the electrode and plasma capacitances under etch-favorable operating conditions).

Decreasing system Q broadens the impedance match space of the system, so that its performance is not as susceptible to changes in plasma conditions or deviations from manufacturing tolerances. For example, the electrode-plasma resonance may fluctuate due to fluctuations in plasma conditions. With a smaller Q, the resonance between the stub 135 and the electrode-plasma combination that is necessary for an impedance match (as described previously in this specification) changes less for a given change in the plasma-electrode resonance. As a result, fluctuations in plasma conditions have less effect on the impedance match. Specifically, a given deviation in plasma operating conditions produces a smaller increase in VSWR at the output of RF generators 150, 220. Thus, the reactor may be operated in a wider window of plasma process conditions (pressure, source power level, source power frequency, plasma density, etc). Moreover, manufacturing tolerances may be relaxed to save cost and a more uniform performance among reactors of the same model design is achieved, a significant advantage. A related advantage is that the same reactor may have a sufficiently wide process window to be useful for operating different process recipes and different applications, such as metal etch, dielectric etch and/or chemical vapor deposition.

Another choice that broadens the tuning space or decreases the system Q is to decrease the characteristic impedance of the stub 135. However, the stub characteristic impedance exceeds the generator output impedance, to preserve adequate match space. Therefore, in the one embodiment, the system Q is reduced, but only to the extent of reducing the amount by which the characteristic impedance of the stub 135 exceeds the output impedance of the signal generators 150, 220.

The characteristic impedance of the coaxial stub 135 is a function of the radii of the inner and outer conductors 140, 145 and of the dielectric constant of the insulator 147 therebetween. The stub characteristic impedance is chosen to provide the requisite impedance transformation between the output impedance of the plasma power sources 150, 220 and the input impedance at the electrode 135. This characteristic impedance lies between a minimum characteristic impedance and a maximum characteristic impedance. Changing the characteristic impedance of the stub 135 changes the waveforms of FIG. 2 and therefore changes the desired location of the taps 160, 230 (i.e., its displacement, A, from the far end of the stub 135).

The ion energy at the substrate surface can be controlled independently of the plasma density/overhead electrode power. Such independent control of the ion energy is achieved by applying an HF frequency bias power source to the substrate. This frequency, (typically 13.56 MHz) is significantly lower than the VHF power applied to the overhead electrode that governs plasma density. Bias power is applied to the substrate by a bias power HF signal generator 200 coupled through a conventional impedance match circuit 210 to the substrate support 105. The power level of the bias generator 200 controls the ion energy near the substrate surface, and is generally a fraction of the power level of the plasma source power generator 150.

As referred to above, the coaxial stub 135 includes a shorting conductor 165 at the outer stub end providing a short circuit between the inner and outer coaxial stub conductors 140, 145. The shorting conductor 165 establishes the location of the VHF standing wave current peak and the VHF standing wave voltage null as in FIG. 2. However, the shorting conductor 165 does not short out the VHF applied power, because of the coupling of the stub resonance and the plasma/electrode resonance, both of which between the VHF source power frequencies. The conductor 165 does appear as a direct short to ground for other frequencies, however, such as the HF bias power source (from the HF bias generator 200) applied to the substrate. It also shorts to ground higher frequencies such as harmonics of the VHF source power frequency generated in the plasma sheath.

The combination of the substrate and substrate support 205, the HF impedance match circuit 210 and the HF bias power source 200 connected thereto provides a very low impedance or near short to ground for the VHF power applied to the overhead electrode. As a result, the system is cross-grounded, the HF bias signal being returned to ground through the overhead electrode 125 and the shorted coaxial stub 135, and the VHF power signal on the overhead electrode 135 being returned to ground through a very low impedance path (for VHF) through the substrate, the HF bias impedance match 210 and the HF bias power generator 200.

The exposed portion of the chamber side wall between the plane of the substrate and the plane of the overhead electrode 125 plays little or no role as a direct return path for the VHF power applied to the overhead electrode 125 because of the large area of the electrode 125 and the relatively short electrode-to-substrate gap. In fact, the side wall of the chamber may be isolated from the plasma using magnetic isolation or a dielectric coating or an annular dielectric insert or removable liner.

In order to confine current flow of the VHF plasma source power emanating from the overhead electrode 125 within the vertical electrode-to-pedestal pathway and away from other parts of the chamber 100 such as the sidewall, the effective ground or return electrode area in the plane of the substrate 110 is enlarged beyond the physical area of the substrate or substrate support 105, so that it exceeds the area of the overhead electrode 125. This is achieved by the provision of the annular semiconductor ring 115 generally coplanar with and surrounding the substrate 110. The semiconductor ring 115 provides a stray capacitance to the grounded chamber body and thereby extends the effective radius of the “return” electrode in the plane of the substrate 110 for the VHF power applied to the overhead electrode. The semiconductor ring 115 is insulated from the grounded chamber body by the dielectric ring 120. The thickness and dielectric constant of the ring 120 is selected to achieve a desirable ratio of VHF ground currents through the substrate 110 and through the semiconductor ring 115. In one embodiment, the dielectric ring 120 is quartz, having a dielectric constant of 9 and was of a thickness of 10 mm.

In order to confine current flow from the HF plasma bias power from the bias generator 200 within the vertical path between the surface of the substrate and the electrode 135 and avoid current flow to other parts of the chamber (e.g., the sidewall), the overhead electrode 135 provides an effective HF return electrode area significantly greater than the area of the substrate or substrate support 105. The semiconductor ring 115 in the plane of the substrate support 105 does not play a significant role in coupling the HF bias power into the chamber, so that the effective electrode area for coupling the HF bias power is essentially confined to the area of the substrate and substrate support 105.

In one embodiment, plasma stability is enhanced by eliminating D.C. coupling of the plasma to the shorting conductor 165 connected across the inner and outer stub conductors 140, 145 at the back of the stub 135. This is accomplished by the provision of the thin capacitive ring 180 between the coaxial stub inner conductor 140 and the electrode 125. In the embodiment of FIG. 1, the ring 180 is sandwiched between the electrode 125 on the bottom and the conductive annular inner housing support 176. In the exemplary embodiments described herein, the capacitive ring 180 had a capacitance of about 180 picoFarads, depending on the frequency of the bias chosen, about 13 MHz. With such a value of capacitance, the capacitive ring 180 does not impede the cross-grounding feature described above. In the cross-grounding feature, the HF bias signal on the substrate pedestal is returned to the RF return terminal of the HF bias generators 150, 220 via the stub 135 while the VHF source power signal from the electrode 125 is returned to the RF return terminal of the VHF source power generator 150 via the substrate pedestal.

In another embodiment, a single stub, taking advantage of the quarter wavelength requirement to add a different frequency, is configure with a length N(λ/2), where N is a positive whole number. For example, a 160 MHz and 320 MHz signal may be applied to the stub to energize gas within the chamber, however, plasma coupling laws will render the upper frequency towards 250 MHz.

While embodiments of the invention described in detail herein are adapted for silicon and metal etch, the invention is also advantageous for choices of plasma operating conditions other than those described above, including different ion densities, different plasma source power levels, different chamber pressures. It should also be apparent from this disclosure that more than two VHF generators could be utilized with additional taps added to the stub 135 to accommodate the additional sources. These variations will produce different plasma capacitances, requiring different electrode capacitances and different electrode-plasma resonant frequencies and therefore require different plasma source power frequencies and stub resonant frequencies from those described above. Also, different substrate diameters and different plasma processes such as chemical vapor deposition may well have different operating regimes for source power and chamber pressure. Yet it is believed that under these various applications, the invention will generally enhance the process window and stability as in the embodiment described above.

While the foregoing is directed to various embodiments of the present invention, other and further embodiments of the invention may be devised without departing from the basic scope thereof, and the scope thereof is determined by the claims that follow.

1. A plasma reactor for processing a semiconductor workpiece, comprising:
a reactor chamber having a chamber wall and containing a workpiece support for holding the semiconductor workpiece;
an overhead electrode overlying said workpiece support, said electrode comprising a portion of said chamber wall;
a plurality of RF power generators, where each generator supplies power at a frequency to said overhead electrode;
a fixed impedance matching element connected between said plurality of generators and said overhead electrode;
said overhead electrode having a reactance that forms a resonance with the plasma at an electrode-plasma resonant frequency that is proximate the frequency of each of said plurality of generators.

2. The reactor of claim 1 wherein the electrode-plasma resonant frequency is between a first frequency of a first RF generator and a second frequency of a second RF generator.

3. The reactor of claim 1 wherein the frequencies of said plurality of RF power generators and the electrode-plasma resonant frequency are VHF frequencies.

4. The reactor of claim 1 wherein, said fixed impedance match element has a match element resonant frequency.

5. The reactor of claim 4 wherein the match element resonant frequency is between a first frequency of a first RF generator and a second frequency of a second RF generator.

6. The reactor of claim 4 wherein each frequency of said plurality of generators, said corresponding plasma frequencies and said corresponding match element resonant frequencies are all VHF frequencies.

7. The reactor of claim 4 wherein said fixed impedance match element comprises:
a coaxial stub having a near end thereof adjacent said overhead electrode for coupling power from said plurality of RF power generators to said overhead electrode and providing an impedance transformation therebetween, said coaxial stub comprising:
an inner conductor connected at said near end to said overhead electrode,
an outer conductor around and spaced from said inner conductor and connected at said near end to an RF return potential of each of said plurality of RF power generators,
a plurality of taps at selected locations along the axial length of said stub, said plurality of taps comprising a connection between said inner conductor and an output terminal of said plurality of RF power generators.

8. The reactor of claim 7 further comprising a shorting conductor connected at a far end of said stub opposite said near end to said inner and outer connectors, whereby said far end of said stub is an electrical short.

9. The reactor of claim 7 wherein the length of said stub between said near and far ends is equal to a multiple of a quarter wavelength of said match element resonant frequency of the stub.

10. The reactor of claim 9 wherein the match element resonant frequency is between a first frequency of a first RF generator and a second frequency of a second RF generator.

11. The reactor of claim 7 wherein said selected location is a location along the length of said stub at which a ratio between a standing wave voltage and a standing wave current in said stub is at least nearly equal to an output impedance of said plurality of RF power generators.

12. A method of processing a semiconductor substrate in a plasma reactor chamber, comprising:
providing an overhead electrode having an electrode capacitance and a plurality of VHF power generators;
coupling said plurality of VHF power generators to said overhead electrode through an impedance matching stub having a length that is a multiple of about one quarter of a VHF stub frequency and connected at one end thereof to said overhead electrode and connected at a plurality of tap point therealong corresponding to each of said plurality of VHF power generators;
applying an amount of power from said plurality of VHF power generators to said overhead electrode to maintain a plasma density at which said plasma and electrode together tend to resonate at a VHF frequency between the VHF frequency of each of said plurality of VHF power generators.

13. The method of claim 12 further comprising:
locating said plurality of taps near an axial location along the length of said stub at which the ratio between the standing wave voltage and standing wave current equals the output impedance of said VHF generator.

14. The method of claim 12 wherein the plasma VHF frequency and the stub VHF frequency is between the VHF frequencies generated by said plurality of VHF generators.

15. A plasma reactor for processing a semiconductor workpiece, comprising:
a reactor chamber having a chamber wall and containing a workpiece support for holding the semiconductor workpiece;
a planar electrode at least generally facing said workpiece support;
a coaxial stub having a near end thereof adjacent said overhead electrode said coaxial stub having a cylindrical axis of symmetry generally non-parallel to a plane of said planar electrode at an interface therebetween, and comprising:
an inner conductor connected at said near end to said overhead electrode,
an outer conductor around and spaced from said inner conductor;
a plurality of RF generators connected across said inner and outer conductors.

16. The reactor of claim 15 wherein said outer conductor and said substrate support are connected to an RF return potential of each of said plurality of RF generators.

17. The reactor of claim 16 further comprising a plurality of coaxial cables providing the connection between said coaxial stub and said plurality of RF generators, said coaxial cables having a center conductor connected at one end to an RF output terminal of each of said RF generators and connected at an opposite end to said electrode, each of said coaxial cables further having an outer conductor connected at one end to an RF return potential of each of said plurality of RF generators and coupled at an opposite end to said portions of said chamber electrically connected to said substrate support.

18. The reactor of claim 17 wherein the connections between said inner conductors of said coaxial stub and each of said coaxial cables are at tap points along the length of said coaxial stub at which the ratio of the standing wave voltage and current in said stub is at least approximately equal to said characteristic impedance of said cable.

19. The reactor of claim 18 further comprising a shorting conductor connected between said inner and outer conductors at a far end of said stub away from said electrode.

20. The reactor of claim 19 wherein the length of said stub between said near and far ends is equal to a multiple of a quarter wavelength of a stub resonant frequency between the frequencies of each of said plurality of RF generators.

21. The reactor of claim 20 wherein the length of said stub between said near and far ends is equal to a half wavelength of the stub resonant frequency.

22. The reactor of claim 20 wherein each of said plurality of RF power generators produces a VHF power signal at a VHF frequency, said stub resonant frequency being a VHF frequency between the VHF frequencies of said plurality of generators.

23. The reactor of claim 22 wherein said overhead electrode and the plasma formed in said chamber resonate together at a VHF electrode-plasma resonant frequency, said VHF electrode-plasma resonant frequency being between the VHF frequencies of said plurality of generators.
